(19) United States
(12) Patent Application Publication
(10) Pub. No.: US 2011/0269289 A1
(43) Pub. Date: Nov. 3, 2011

(54) TRANSISTOR DEVICE AND A METHOD OF MANUFACTURING THE SAME

(75) Inventors: Philippe Meunier-Beillard, Kortenberg (BE); Hans Mertens, Leuven (BE)

(73) Assignee: NXP B.V., Eindhoven (NL)

(21) Appl. No.: 13/054,483

(22) PCT Filed: Jul. 8, 2009
(86) PCT No.: PCT/IB2009/052970

§ 371 Date: May 9, 2011

(30) Foreign Application Priority Data
Jul. 14, 2008 (EP) 08104737.5

(51) Int. Cl. H01L 21/331

(52) U.S. Cl. 438/314; 438/353; 257/E21.37; 257/E21.371

(57) ABSTRACT

A method of manufacturing a transistor device (600), wherein the method comprises forming a trench (106) in a substrate (102), only partially filling the trench (106) with electrically insulating material (202), and implanting a collector region (304) of a bipolar transistor (608) of the transistor device (600) through the only partially filled trench (106).

### FIELD OF THE INVENTION

The invention relates to a transistor device.

Moreover, the invention relates to a method of manufacturing a transistor device.

### BACKGROUND OF THE INVENTION

In semiconductor technology, the efficient manufacture of field effect transistors is essential. For modern applications, the demands on the quality and on the performance of transistors increases.

US 2007/298578 discloses a bipolar transistor with dual shallow trench isolation for reducing the parasitic component of the base to collector capacitance and base resistance. The structure includes a semiconductor substrate having at least a pair of neighboring first shallow trench isolation (STI) regions disposed therein. The pair of neighboring first STI regions defines an active area in the substrate. The structure also includes a collector disposed in the active area of the semiconductor substrate, a base layer disposed atop a surface of the semiconductor substrate in the active area, and a raised extrinsic base disposed on the base layer. The raised extrinsic base has an opening to a portion of the base layer. An emitter is located in the opening and extending on a portion of the patterned raised extrinsic base; the emitter is spaced apart and isolated from the raised extrinsic base. Moreover, and in addition to the first STI region, a second shallow trench isolation (STI) region is present in the semiconductor substrate which extends inward from each pair of said first shallow trench isolation regions towards said collector. The second STI region has an inner sidewall surface that is sloped.

D. Knoll et al., “A Low-Cost, High-Performance, High-Voltage Complementary BiCMOS Process”, Electron Devices Meeting, 2006, IEDM '06, International, discloses a low-cost, high-performance, high-voltage complementary SiGe:C BiCMOS process. This technology offers three npn SiGe:C devices with f_{T}/BV_{CEO} values of 40 GHz/5V, 63 GHz/3.5V, and 120 GHz/2.1V together with a 32 GHz f_{T}/35 GHz fₘₐₓ/4.4V pnp SiGe:C HBT by adding only three bipolar masks to the underlying RF-CMOS process. With two additional implant masks, a 150 GHz, 2.2V npn HBT and either a 43 GHz f_{T}/65 GHz fₘₐₓ 4.2V pnp or a 38 GHz f_{T}/70 GHz fₘₐₓ, 5.8V pnp device can be fabricated additionally (in the npn case) or alternatively (pnp case) to the devices of the 3-mask module.

However, conventional transistor manufacture procedures may lack sufficient flexibility for designing transistor properties.

### OBJECT AND SUMMARY OF THE INVENTION

It is an object of the invention to provide a transistor architecture which can be manufactured with sufficient flexibility.

In order to achieve the object defined above, a transistor device and a method of manufacturing a transistor device according to the independent claims are provided.

According to an exemplary embodiment of the invention, a method of manufacturing a transistor device is provided, wherein the method comprises forming a trench in a substrate, only partially (that is not completely) filling the trench with electrically insulating material, and implanting (for instance by ion implantation) a collector region of a bipolar transistor of the transistor device through the only partially filled trench (particularly in a manner that the implanted ions traverse the partially filled trench before being implanted in the substrate to thereby form the collector).

According to another exemplary embodiment of the invention, a transistor device is provided which is manufactured according to the above-mentioned method.

The term “bipolar transistor” may denote a type of transistor being a three-terminal device constructed of doped semiconductor material, which may be used in high frequency or amplifying or switching applications. A bipolar transistor may comprise a pair of pn-junction diodes that are joined back-to-back. This forms a sort of a sandwich of three kinds of semiconductor materials. There are therefore two kinds of bipolar sandwiches, the npn and pnp varieties. The three layers of the sandwich may be denoted as the collector, base, and emitter. A heterojunction bipolar transistor (HBT) is a special bipolar transistor that can handle signals of very high frequencies up to several hundred GHz and more and may be employed in ultrafast circuits such as radio-frequency (RF) systems. Embodiments of the invention relate to the manufacture of a collector of a bipolar transistor, whereas base and emitter may be manufactured using a convention process.

The term “field effect transistor” (FET) may denote a transistor in which an output current (source-drain current) may be controlled by the voltage applied to a gate which can be a MOS structure (MOSFET). Such a field effect transistor may be part of a monolithically integrated circuit and may provide a function such as a memory function, a logic function, a switch function and/or an amplifier function.

The term “substrate” may denote any suitable material, such as a semiconductor, glass, plastic, etc. According to an exemplary embodiment, the term “substrate” may be used to define generally the elements for layers that underlie and/or overlie a layer or portions of interest. Also, the substrate may be any other base on which a layer is formed, for example a semiconductor wafer such as a silicon wafer or silicon chip. According to an exemplary embodiment, a monocrystalline substrate may be employed.

According to an exemplary embodiment of the invention, an improved collector implanting architecture is provided which allows implanting a doped collector region partially below a partially filled trench. When the trench, particularly an STI trench, is only partially filled, it is possible to implant the dopant later forming the collector region through the STI trench without losing too much of the dopant in the STI and simultaneously protecting a surface of a semiconductor substrate against an excessive doping. Furthermore, such a procedure may allow reducing the energy of the implant, which allows using higher doping rates resulting in a reduced collector resistance. Simultaneously, such architecture may allow keeping parasitic collector-substrate capacitances low, resulting in proper electric properties of a corresponding transistor device.

According to an exemplary embodiment of the invention, a method of forming a heterojunction bipolar transistor is provided, the method comprising the steps of providing a shallow trench isolation (STI) cavity within a substrate, only partly filling the STI cavity with a semiconductor oxide layer, forming collector regions in the substrate by implanting dopants through the semiconductor oxide layer, and sealing or filling the STI cavity (with semiconductor oxide). This may allow achieving higher flexibility in the design of highly-doped regions below the STI trenches compared to conventional fabrication methods. Exemplary applications of embodiments of the invention are low cost BiCMOS (for instance for TV tuners or satellite) systems.

According to an exemplary embodiment of the invention, an improved implanted collector formation may be made possible. Particularly, a method for forming an HBT is provided where collector regions are implanted when shallow trench isolation being only partly filled.

Embodiments of the invention describe a method to improve the formation of an implanted collector for a low complexity bipolar transistor. A silicon oxide thickness in the STI may be reduced in order to ensure a better collector design.

According to an aspect of the invention, the implantations of the highly-doped regions below the STI trenches are performed when the trenches are only partly filled with silicon oxide. In one embodiment, this may be done by performing the implantations after STI liner oxidation. In another embodiment, this may be done after STI formation by using a silicon nitride/silicon oxide stack as screening/protective implant layer (instead of only silicon oxide), using for instance a deep-ultraviolet (DUV) mask to remove some semiconductor oxide in the STI, and preventing the creation of topography (in the STI) by replacing the semiconductor nitride with another material (like semiconductor oxide).

In the following, further exemplary embodiments of the method will be explained. However, these embodiments also apply to the transistor device.

The method may comprise filling at least a part of the partially filled trench (that is a void remaining in the trench after the partial filling) after the implantation. In other words, the STI trench may be filled partially before the implantation procedure, and may be subsequently filled partially or entirely. This may avoid voids within the semiconductor structure, which voids may be the origin of mechanical instabilities.

Only partially filling the trench with electrically insulating material may be performed by shallow trench insulation (STI) liner formation. After having formed the STI trench, particularly using lithography and etching procedure, it is possible to cover a surface of the trench with an electrically insulating material such as silicon oxide. This may be performed by thermally oxidizing the walls of the trench, which is delimited by semiconductor material. Alternatively, a thin layer of electrically insulating lining material may be deposited covering the entire surface of the STI trench. This lining layer may protect lower lying layers before performing an implanting procedure.

Only partially filling the trench with electrically insulating material may be performed alternatively by filling the trench with a sacrificial material (that is a material that is to be removed afterwards), forming a protection layer (or a cover layer) on (or above) the sacrificial material (which may be an electrically insulating material such as silicon nitride), exposing a portion of the sacrificial material by patterning the protection layer (for instance by forming one or more access holes in the protection layer to provide vent holes for subsequently removing sacrificial material through this access hole or holes), and removing sacrificial material through the patterned protection layer (more precisely through the access holes thereof). Etching may perform the removing procedure, whereas access to the sacrificial material filling at least partially the trench may be provided via the one or more access holes of the patterned protection layer through which an etchant may operate. With such an architecture, it is possible to keep the protection layer during the implantation procedure to protect lower lying layers from being damaged by the implantation, and by simultaneously allowing the STI trench to be at least partially transparent for the implantation ions.

It is possible that only a part of the sacrificial material is removed through the patterned protection layer. In such an embodiment, it is possible that another part of the sacrificial material remains within the STI trench. Alternatively, the entire sacrificial material may be removed.

The method may further comprise filling material through the patterned protection layer into at least a part of a void formed in the trench by the removing of sacrificial material. In order to avoid mechanical instabilities of such a bridge-like structure which may be formed after the removal of the sacrificial layer, it is possible to partially or entirely fill a void remaining after the removal of the sacrificial material. Such a filling procedure may include thickening a bridge formed by the protection layer and interrupted by the one or more access holes, closing the one or more access holes, providing a solid support that completely covers the former void, etc.

The method may further comprise planarizing a surface of the layer sequence obtained after filling the material into the void. This may prevent an undesired surface topography which may result in mechanical instabilities of the layer sequence. The planarization may be performed using Chemical Mechanical Polishing (CMP).

The method may further comprise depositing an electrically conductive material over the trench (for instance on the protection layer). Such an electrically conductive material may be, for instance, polycrystalline silicon material which may serve as an electrical contact member, for instance for connecting a base region of the bipolar transistor and/or a gate region of a field effect transistor which can be formed on and in the same substrate and which can be coupled electrically to the bipolar transistor.

The trench may be a shallow trench isolation (STI) trench, that is a trench formed in the context of the formation of a shallow trench isolation. Shallow trench isolation (STI), which may also be denoted as “Box Isolation Technique”, is an integrated circuit feature which prevents electrical current leakage between adjacent semiconductor device components. Other CMOS technologies and non-MOS technologies may use isolation based on LOCOS (LOCal Oxidation of Silicon).

Thus, a field effect transistor may be formed at least partially simultaneously with the forming of the bipolar transistor, wherein a portion of the substrate accommodating the field effect transistor may be protected by a cover layer during the implantation. By taking this measure, the field effect transistor can be prevented from being deteriorated by the implant procedure for forming the collector region. Thus it is possible to integrate both CMOS and bipolar transistors on the same substrate. Exemplary embodiments of the invention may be applied for high frequency applications, particularly applications in a frequency domain between tenths of Gigahertz to hundreds of Gigahertz and more. Examples are radar system and imaging systems. According to an exemplary embodiment, any RF application may be realized using the transistor device.

An exemplary embodiment of the invention combines a highly efficient bipolar transistor manufacture procedure with the integration of a field effect transistor in the same substrate. Simultaneously, the FET may be optimized regarding requirements of logic applications or high-frequency applications, and the bipolar transistor may be designed specifically regarding requirements of high-frequency applications.

The substrate may be a semiconductor substrate. The transistor device may be monolithically integrated in the semiconductor substrate, particularly comprising one of the group consisting of a group IV semiconductor (such as silicon or germanium), or a III-V semiconductor (such as gallium arsenide).

For any method step, any conventional procedure as known from semiconductor technology may be implemented. Forming layers or components may include deposition techniques like CVD (chemical vapour deposition), PECVD (plasma enhanced chemical vapour deposition), ALD (atomic layer deposition), oxidation or sputtering. Removing layers or components may include etching techniques like wet etching, plasma etching, etc., as well as patterning techniques like optical lithography, UV lithography, electron beam lithography, etc.

Embodiments of the invention are not bound to specific materials, so that many different materials may be used. For conductive structures, it may be possible to use metallization structures, silicide structures or polysilicon structures. For semiconductor regions or components, crystalline silicon may be used. For insulating portions, silicon oxide or silicon nitride may be used.

The transistor may be formed on a purely crystalline silicon wafer or on an SOI wafer (Silicon On Insulator).

Any process technologies like CMOS, BIPOLAR, BICMOS may be implemented.

The aspects defined above and further aspects of the invention are apparent from the examples of embodiment to be described hereinafter and are explained with reference to these examples of embodiment.

### BRIEF DESCRIPTION OF THE DRAWINGS

The invention will be described in more detail hereinafter with reference to examples of embodiment but to which the invention is not limited.

FIG. 1 to FIG. 6 illustrate cross-sectional views of layer sequences obtained during a method of manufacturing a transistor device according to an exemplary embodiment of the invention.

FIG. 7 to FIG. 13, FIG. 16 to FIG. 20 show cross-sectional views of layer sequences obtained during a method of manufacturing a transistor device according to another exemplary embodiment of the invention.

FIG. 14 and FIG. 15 show diagrams illustrating the dependency between an arsenic implant concentration in silicon and different oxide thicknesses.

### DESCRIPTION OF EMBODIMENTS

The illustration in the drawing is schematical. In different drawings, similar or identical elements are provided with the same reference signs.

In the following, some basic recognitions of the present inventors will be mentioned based on which exemplary embodiments of the invention have been developed.

For modern CMOS platforms, it is desired to implement good RF options (like high frequency and/or high breakdown voltage) at reasonable cost. Heterojunction bipolar transistors (HBTs) have proven to be key enablers for RF options in CMOS generations, such as CMOS25 and CMOS18. Accordingly, HBTs are promising devices for new CMOS generations as well. Especially the so-called low-complexity HBT is considered as an excellent candidate to achieve good RF performance at reasonable cost.

The low-complexity HBT does preferably not include an epitaxially buried subcollector layer because of cost issues. Since epitaxially buried subcollector layers may be important in HBT designs, the consequence is that special attention is needed to optimize the collector of a low-complexity HBT. Desired properties are low collector-substrate capacitance, low base-collector capacitance and low collector resistance. The low collector resistance may be achieved by implants that provide enough doping under a shallow trench isolation (STI). Highly doped regions below the STI trenches ensure a good link between the collector and the collector contact. Since a typical STI thickness in a modern CMOS generation is ˜370 nm, high-energy implants may be required to get the dopants at the appropriate depth. These implants should be necessarily done after STI formation, because the high thermal budget of the STI module might lead to unwanted dopant diffusion if the implants were done first.

A drawback of conventional high-energy implants is that they may induce a lot of crystal damage. The damage has to be repaired by anneal treatments to enable the growth of a high-quality base-emitter stack on top of the implanted substrate. These anneal treatments may lead to unwanted diffusion of dopants in the collector region. Consequently, it may be very difficult to design and fabricate well-defined drift regions having a sufficiently sharp transition between the drift region and the “subcollector” (ensuring an optimal trade-off between resistance and capacitance). A possible solution to this problem is the formation of a thinner STI, which may be referred to as Second Shallow Trench (SSTR).

According to an exemplary embodiment of the invention, it is possible to implement a method that provides more flexibility in the design of highly-doped regions below the STI trenches compared to conventional fabrication methods, without that the depth of the STI trenches is reduced. Two exemplary implementations will be mentioned in the following, although alternatives are possible. Both implementations are based on performing the implantations when the STI trenches are only partly filled with silicon oxide. This may allow to lower the implantation energy that is required to get the dopants at the appropriate depth. Because low implant energies result in less damage, the implantation dose can be increased, which reduces the collector resistance which is a major advantage. Embodiments of the invention do not require additional masks compared to conventional methods to fabricate low-complexity HBTs.

In a first implementation, the implant may be done within the STI module (that is after the STI liner oxidation, but before trench fill). By performing the implant after STI liner oxidation, the high thermal budget of this step has no effect on the doping profile.

In a second implementation, two standard CMOS masks (the threshold voltage adjustment masks which may be denoted as ADHVT n and ADHVT p, wherein ADHVT denotes Additional High VT implantation) may be used to create cavities in the STI oxide after STI formation. This embodiment requires a few extra deposition and etch steps, but an advantage is that the doping profile is also independent of the thermal budget of the STI anneal (for instance around 1000° C.) and the sacrificial oxide prior the well implant (for instance performed after the trench fill around 1100° C.).

Both implementations are described in detail below.

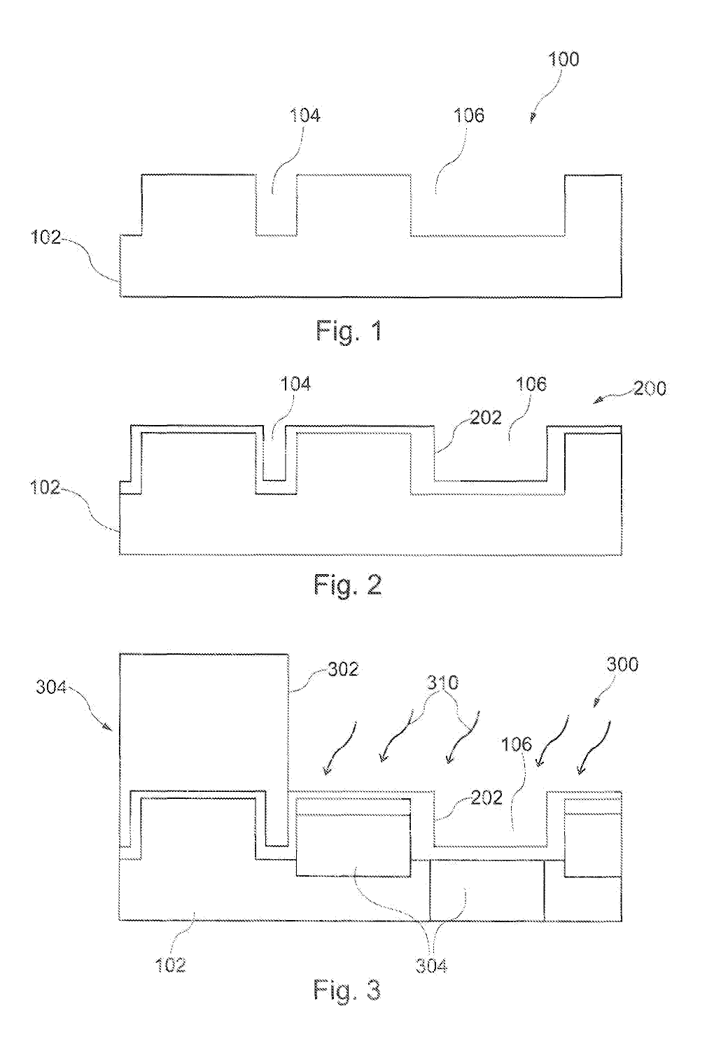

In the following, referring to FIG. 1 to FIG. 6, a method of manufacturing a transistor device according to an exemplary embodiment of the invention according to the first implementation will be explained in detail.

FIG. 1 illustrates a cross-sectional view 100 of a silicon substrate 102 in which trenches 104, 106 have been formed by lithography and etching. The trenches 104, 106 serve for shallow trench isolation (STI) formation.

In order to obtain a layer sequence 200 shown in FIG. 2, the surface of the layer sequence 100 is made subject to an STI liner oxidation procedure so that an STI liner layer 202 is formed to cover the entire surface of the patterned silicon substrate 102.

In order to obtain a layer sequence 300 shown in FIG. 3, a photoresist layer 302 is deposited and patterned to cover a surface portion 304 on which a field effect transistor (not shown) is formed or has at least partially been formed before. The photoresist 302 protects the field effect transistor from being deteriorated or negatively influenced by the further processing steps.

Subsequently, an ion implantation procedure is performed (indicated schematically by reference numeral 310) with the help of the mask 302 which results in a doping profile indicated with reference numeral 304 which represents a collector region of a bipolar transistor formed during the manufacture procedure.

The method steps performed in accordance with FIG. 3 show main differences of the described implementation as compared to a standard bipolar transistor manufacture process. Particularly, base and emitter of the bipolar transistor may be manufactured in a conventional manner. Embodiments of the invention concentrate on an improved manufacture of the collector region 304.

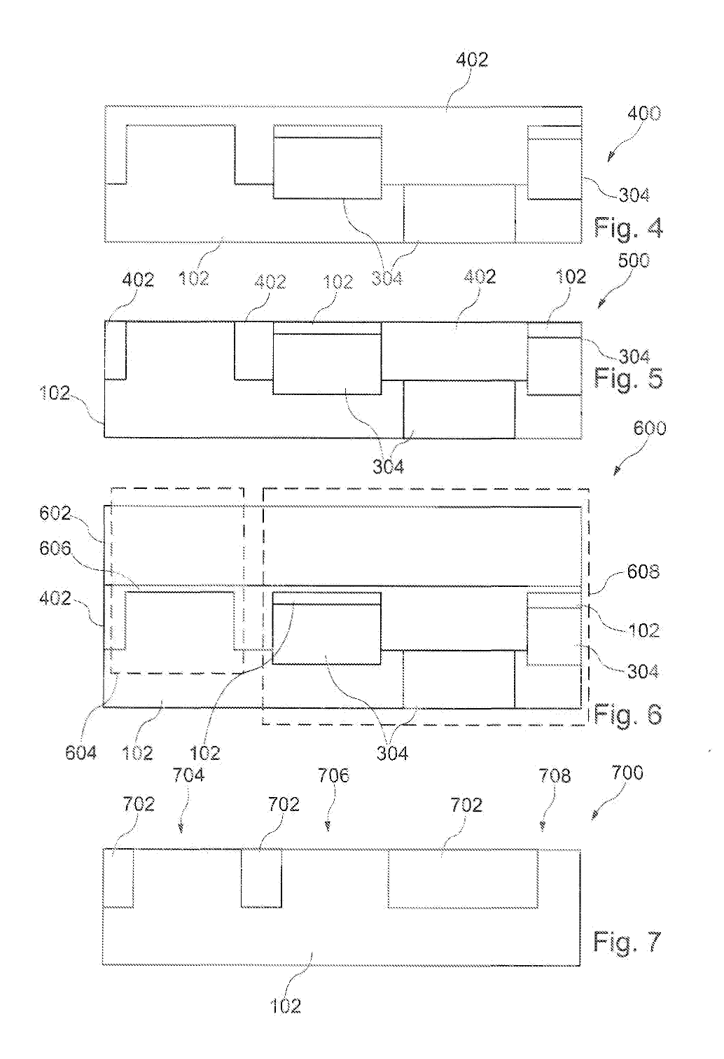

In order to obtain a layer sequence 400 shown in FIG. 4, the photoresist 302 is removed (for instance by stripping) from the layer resistance 300. Subsequently, an electrically insulating material such as silicon oxide is deposited on the resulting layer sequence to thereby fill, inter alia, the STI trenches 104, 106. Consequently, an electrically insulating layer 402 covering the entire surface of the layer sequence 400 is formed.

In order to obtain a layer sequence 500 shown in FIG. 5, a planarization procedure is performed (for instance by Chemical Mechanical Polishing, CMP) and stopping on top of the silicon protrusions of the former silicon substrate 102 as stop layers. In the standard STI module, a silicon oxide/silicon nitride stack is deposited prior the trench etch in FIG. 1. The silicon nitride layer is usually used as CMP stop layer (see FIG. 5). This silicon nitride layer is usually removed after the planarization.

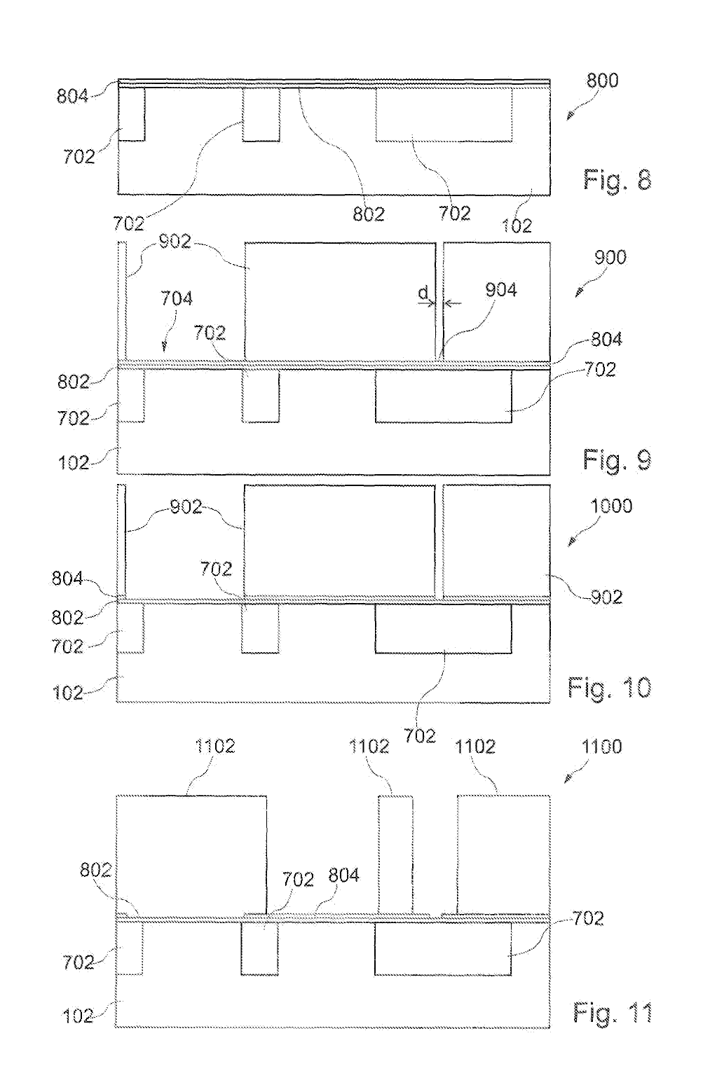

In order to obtain a transistor device 600 according to an exemplary embodiment as shown in FIG. 6, a gate insulating layer 606 is deposited (or formed by thermal oxidation of a surface of the silicon islands 102). Subsequently, a polysilicon layer 602 is deposited on top of the obtained layer sequence.

Thus, a field effect transistor 604 is formed in a first surface portion of the layer sequence 600. For this field effect transistor 604, the polysilicon layer 602 serves as a gate region. The gate region 602 is separated from the silicon channel 102 by the gate insulating layer 606. The remaining portions of the field effect transistor 604 are not shown in the cross-sectional view of FIG. 6.

In another portion of the transistor device 600, a bipolar transistor 608 is formed. For instance, the polysilicon layer 602 may also serve as a base contact of this bipolar transistor 608. However, base and emitter are not shown completely in FIG. 6, only the collector implant 304 is shown in FIG. 6. Base and emitter can be manufactured in accordance with standard procedures.

In the following, referring to FIG. 7 to FIG. 13, FIG. 16 to FIG. 20, a method of manufacturing a transistor device according to another exemplary embodiment of the invention according to the second implementation will be explained in detail.

FIG. 7 shows a layer sequence 700 in which trenches have been etched into a silicon substrate 102, and have been subsequently filled by shallow trench insulation structures 702. A surface region 704 shows an active region where a standard MOSFET is to be implemented, whereas a surface portion 706 shows an active region where a collector contact of a bipolar transistor is to be implemented. A surface portion 708 shows an active region where an emitter contact of the bipolar transistor is to be implemented.

In order to obtain a layer sequence 800 shown in FIG. 8, a silicon oxide layer 802 is deposited on a surface of the layer sequence 700 with a thickness of, for instance, 5 nm. Subsequently, a silicon nitride layer 804 is deposited on the silicon oxide layer 802 with a thickness of, for instance, 5 nm.

Thus, a standard protective silicon oxide is replaced by a silicon oxide 802/silicon nitride 804 stack. The standard n CMOS well and p CMOS well may be formed, but are not shown in FIG. 8. The n well may be used for the collector region formation.

In order to obtain a layer sequence 900 shown in FIG. 9, a photoresist layer 902 is formed and patterned on a surface of the layer sequence 800 to expose selectively the MOSFET region 704 and a narrow portion 904 above the STI isolation 702 shown on the right-hand side of FIG. 9. For this purpose, an ADHVT (Additional High Vt Implant) mask (DUV) is preferred to the well mask (i-line). The small structure 904 having a lateral extension, d, of 100 nm is created onto the STI 702.

A p implant may be performed, and, as can be taken from FIG. 10, exposed portions of the silicon nitride layer 804 may be removed before or after this implant. The silicon oxide layer 802 serves as a stop during the silicon nitride 804 dry etch.

FIG. 10 shows a layer sequence 1000 obtained after having removed the exposed portion of the silicon nitride layer 804, so that the silicon oxide layer 802 is exposed in these two portions.

Subsequently, a standard Additional High VT implant (for example ADHVT n) implant is carried out using a further photoresist mask 1102 patterned, as shown in FIG. 11.

In order to obtain a layer sequence 1200 shown in FIG. 12, a void 1202 is generated within the former STI trench by removing silicon oxide material using a wet etch procedure through an access hole 1204 in the silicon nitride layer 804. A portion of the silicon oxide material 1206 remains within the STI trench which, therefore, remains partially filled.

The silicon oxide material 702 within the STI trench is removed by wet etching through the silicon nitride hole 1204. The resist 1102 and the silicon nitride 804 protect the other regions. The STI width may be around 800 nm and after a 300 nm wet etch, approximately 50 nm of the silicon oxide may remain within the void 1202 (see reference numeral 1206). The fixed contact width and the minimum spacing between two contacts may be 240 nm and 320 nm in CMOS 18 (total 560 nm). About 200 nm of silicon oxide may be removed for a typical STI width of 560 nm.

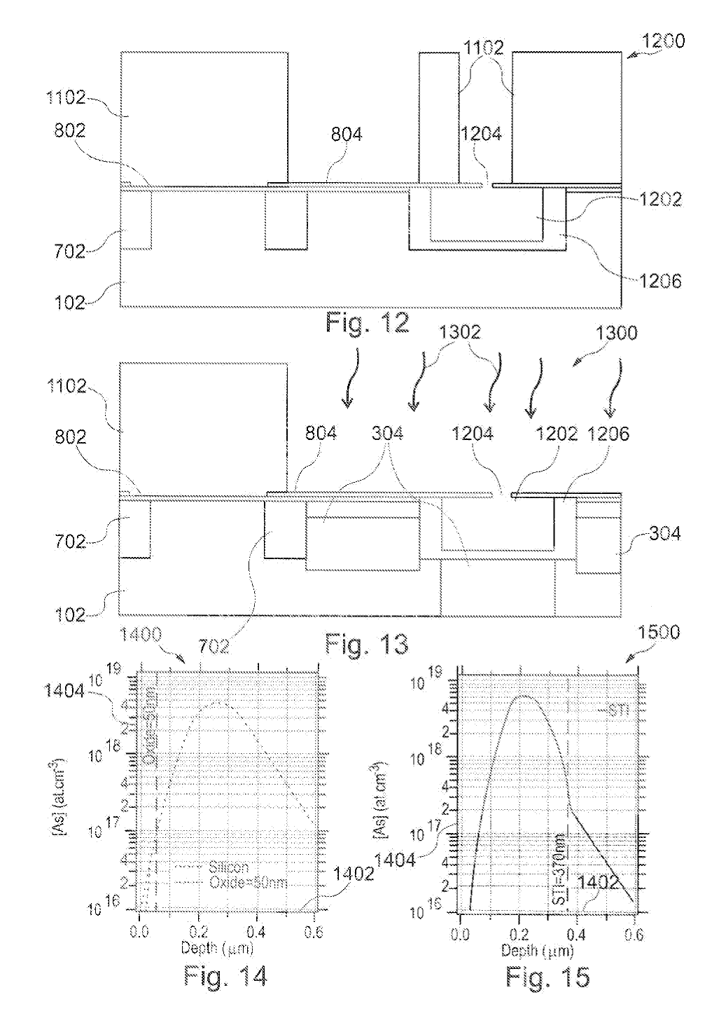

In order to obtain a layer sequence 1300 shown in FIG. 13, a portion of the photoresist 1102 not covering the later field effect transistor is removed, and subsequently a collector implant 1302 procedure is carried out to form the collector implant regions 304 below the partially filled STI trench 1202.

Thus, the collector 304 is implemented with the help of a dedicated mask 1102. The resulting implant is schematically represented with reference numeral 304 in FIG. 13.

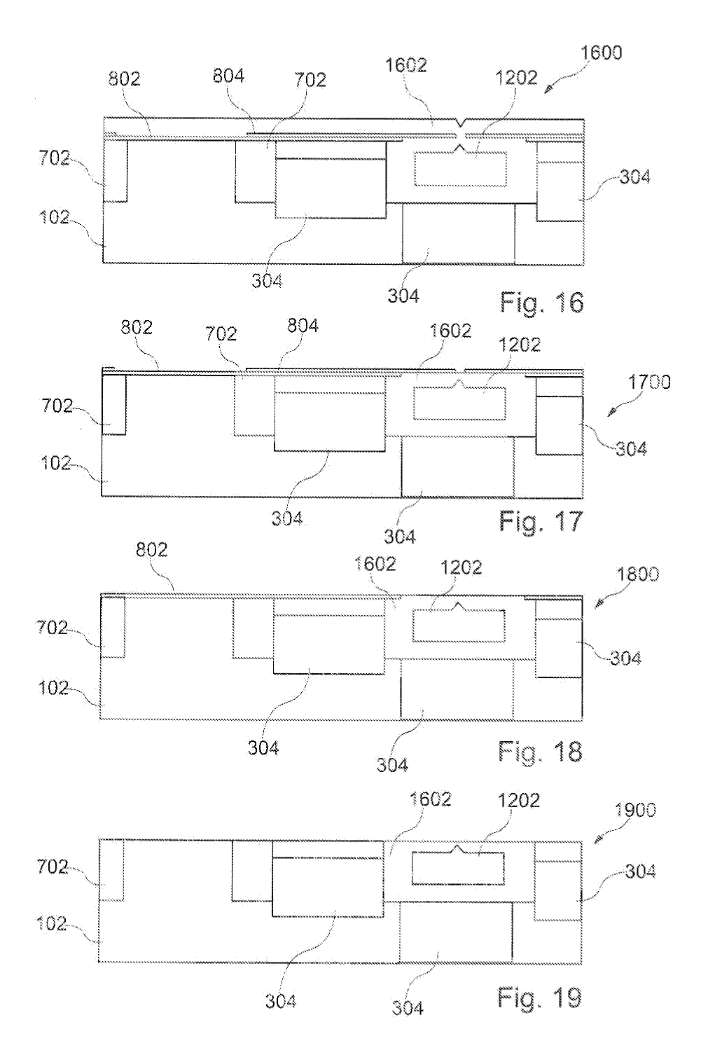

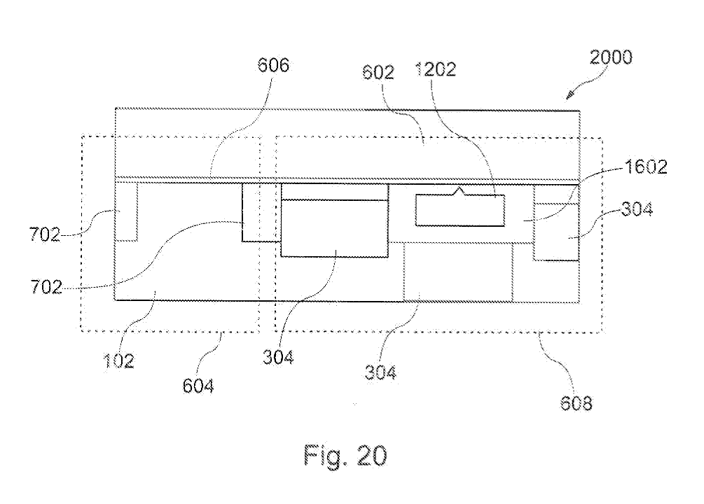

FIG. 14 and FIG. 15 provide further details for understanding the implant procedure shown in FIG. 13.

FIG. 14 shows a diagram 1400 having an abscissa 1402 along which a depth is plotted in nm which has been traversed by implanting ions. Along an ordinate 1404, a corresponding arsenic implantation is plotted in atoms cm⁻³. The corresponding curves are shown in FIG. 14 for silicon and for silicon oxide. FIG. 15 shows a corresponding diagram 1500 for STI.

More particularly, FIG. 14 and FIG. 15 show an arsenic implant (using an implant dose of 1 10¹⁴atoms/cm², energy 400 keV) in silicon through different oxide thicknesses (0, 50 nm and 370 nm). Thus, FIG. 14 and FIG. 15 present a simulated implanted profile at 400 keV through different oxide thicknesses. This implant energy corresponds to the formation of a drift region of about 100 nm. The arsenic material is mainly present in a standard STI oxide thickness of 370 nm. The low arsenic concentration under the STI would create a high resistance link between the collector contact and the collector region. Similar arsenic profiles are obtained with and without a thin oxide layer of 50 nm (see FIG. 15) ensuring a good link between the contact and the collector region. The remaining void within the STI needs to be closed in order to prevent the formation of unwanted topography, as will be explained in the following in more detail.

In order to obtain a layer sequence 1600 shown in FIG. 16, the photoresist 1102 is removed, and a silicon oxide deposition procedure is performed to close the access hole 1204 and the void 1202. Thus, a closing structure 1602 is formed. As an alternative to the closing by silicon oxide material, it is also possible to close the access hole 1204 by polysilicon deposition. As an alternative to the embodiment shown in FIG. 16, the entire void 1202 may be removed by using more fill material.

In order to obtain a layer sequence 1700 shown in FIG. 17, an oxide etching procedure is performed in order to remove silicon oxide material from the surface of the layer sequence 1600. In this context, the silicon nitride layer 804 may be used as a stopping layer.

In order to obtain a layer sequence 1800 shown in FIG. 18, a silicon nitride etch may be performed, using silicon oxide material as a stopping layer.

Furthermore, in order to obtain a layer sequence 1900 shown in FIG. 19, a silicon oxide etch may be performed using silicon material as a stopping layer.

In order to obtain a transistor device 2000 according to an exemplary embodiment of the invention shown in FIG. 20, a polysilicon layer 602 is deposited to form a gate region of a MOSFET 604 and optionally a base contact for a bipolar transistor 608.

Finally, it should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The words “comprising” and “comprises”, and the like, do not exclude the presence of elements or steps other than those listed in any claim or the specification as a whole. The singular reference of an element does not exclude the plural reference of such elements and vice-versa. In a device claim enumerating several means, several of these means may be embodied by one and the same item of software or hardware. The mere fact that certain measures are recited in mutually different dependent claims does not indicate that a combination of these measures cannot be used to advantage.

1. A method of manufacturing a transistor device (600), wherein the method comprises:
forming a trench in a substrate;
only partially filling the trench with electrically insulating material to obtain a partially filled trench;
Depositing a patterned mask over the substrate and the electrically insulating material, wherein the mask is patterned for keeping the electrically insulating material in the trench uncovered, and;
implanting a collector region of a bipolar transistor of the trench substantially through the electrically insulating material under masking of the patterned mask.

2. The method of claim 1, comprising filling at least a part of the partially filled trench after the implanting.

3. The method of claim 1, wherein only partially filling the trench with electrically insulating material is performed by liner formation.

4. The method of claim 1, wherein only partially filling the trench with electrically insulating material is performed by:
filling the trench with a sacrificial material;
forming a protection layer on the sacrificial material;
exposing a portion of the sacrificial material by patterning the protection layer and;
removing a sacrificial material through the patterned protection layer.

5. The method of claim 4, wherein only a part of the sacrificial material is removed through the patterned protection layer.

6. The method of claim 4, comprising filling material through the patterned protection layer into at least a part of a void formed in the trench by the removing of the sacrificial material.

7. The method of claim 6, comprising planarizing a surface of the layer sequence obtained after the filling of the material into the void.

8. The method of claim 1, comprising depositing an electrically conductive material over the trench.

9. The method of claim 8, wherein the electrically conductive material is deposited over the trench to form at least a part of a base contact of the bipolar transistor and/or to form a gate region of a field effect transistor.

10. The method of claim 1, comprising forming a field effect transistor at least partially simultaneously with the forming of the bipolar transistor, wherein a portion of the substrate accommodating the field effect transistor is protected by a cover layer during the implanting.

11. The method of claim 1, wherein the trench is a shallow trench isolation trench.

12. A transistor device, manufactured according to the method of claim 1.

13. The transistor device of claim 12, wherein the bipolar transistor is formed as a heterojunction bipolar transistor.

14. The transistor device of claim 12, further comprising a field effect transistor formed on and/or in the substrate.

15. (canceled)
